(19) United States
(12) Patent Application Publication
(10) Pub. No.: US 2005/0110094 A1
(43) Pub. Date: May 26, 2005

(54) Solid state imaging device and method of driving the same

(76) Inventor: Kazunobu Kuwazawa, Chino-shi (JP)

Correspondence Address: HARNESS, DICKEY & PIERCE, P.L.C., P.O. BOX 828, BLOOMFIELD HILLS, MI, 48303, US

(21) Appl. No.: 10/970,848

(22) Filed: Oct. 21, 2004

(30) Foreign Application Priority Data
Oct. 22, 2003 (JP) 2003-362004

(51) Int. Cl. H01L 27/148

(52) U.S. Cl. 257/359

(57) ABSTRACT

A solid state imaging device includes a plurality of pixels arranged in a matrix form that generates photo-generated electric charges corresponding to incidence light. The device comprises an effective pixel region used for imaging and a non-effective pixel region provided separately from the effective pixel region. Each pixel has an accumulation well which accumulates photo-generated electric charges, a modulation transistor, and a transfer control element which transfers the photo-generated electric charges accumulated in the accumulation well to the modulation transistor. When transferring the photo-generated electric charges accumulated in the accumulation well to the modulation transistor by the transfer control element, the photo-generated electric charges in the effective pixel region and the photo-generated electric charges which do not include the photo-generated electric charges in the effective pixel region are transferred separately at least two times.

### RELATED APPLICATIONS

This application claims priority to Japanese Patent Application No. 2003-362004 filed Oct. 22, 2003 which is hereby expressly incorporated by reference herein in its entirety.

### BACKGROUND

1. Field of the Invention

The present invention relates to a solid state imaging device and a method of driving the same, and in particular to the solid state imaging device that generates photo-generated electric charges corresponding to incident light and a method of driving the same.

2. Description of the Related Art

Solid state imaging devices carried in cellular phones or the like include a CCD (charge coupled device) type image sensor and a CMOS type image sensor. The CCD type image sensor is excellent in picture quality, and the CMOS type image sensor consumes lower power and its process cost is low. In recent years, MOS type solid state imaging devices using a threshold voltage modulation method which combines both high quality picture and low power consumption have been proposed. A MOS type solid state imaging device using the threshold voltage modulation method is disclosed in Japanese Unexamined Patent Publication No. 2002-134729, for example.

In the solid state imaging device of Japanese Unexamined Patent Publication No. 2002-134729, a picture output is obtained by arranging unit pixels in a matrix form and repeating three states of initialization, accumulation, and reading. Moreover, in the solid state imaging device of Japanese Unexamined Patent Publication No. 2002-134729, each unit pixel has a photo-diode, a modulation transistor, and an overflow drain gate. The gate of the modulation transistor is formed in a ring shape.

Electric charges (photo-generated electric charges) generated by light incident upon the photo-diode are transferred to a P-type well region formed under a ring gate, and accumulated in a carrier pocket formed in this region. The threshold voltage of the modulation transistor changes corresponding to the photo-generated electric charges accumulated in the carrier pocket. Accordingly, a signal (pixel signal) corresponding to incident light is obtained from a terminal coupled to the source region of the modulation transistor.

Moreover, in the two dimensional solid state imaging device, in order to realize the so-called electronic shutter mechanism, when transferring the carriers, which are the photo-generated electric charges accumulated in the carrier region, to a signal reading transistor, a technology of batch-transferring carriers of all pixels has been proposed (refer to Japanese Unexamined Patent Publication No. Hei. 6-77455).

However, when using such all pixel batch-transfer technology, in order to turn on a transfer transistor, there is a problem that a power supply circuit having a considerable amount of current driving capability is needed. Specifically, the current instantaneously required at the time of the transfer is expressed as the following formula, for simplicity.
Q=Cg×N/t.tx ⁻⁻⁻ Formula (1)

Here, Q is the amount of required electric charges, Cg is a gate capacity, N is the number of pixels, and t.tx is the time required for the transfer.

However, the chip for a solid state imaging device is area-constrained. Therefore, there may be cases where it is difficult to incorporate a power supply circuit, which needs a large current, on the chip of the solid state imaging device. Moreover, even if the power supply circuit for a large current is incorporated in the chip, the chip size thereby becomes large, and the number of chips obtained from one wafer will decrease, thereby leading to a cost increase in terms of chip manufacturing. Furthermore, it is conceivable, for example, that such a power supply circuit is made an external type, however, the number of parts thereof will increase from the view point of the imaging module, and thus the cost as the imaging module will increase, as a result.

The present invention has been made in view of such a problem, and is intended to provide a solid state imaging device which reduces the maximum amount of current supply required for turning on a transfer transistor, and a method of driving the same.

### SUMMARY

A solid state imaging device according to the present invention, arranges, in a matrix form, a plurality of pixels that generate photo-generated electric charges corresponding to incidence light, and comprises an effective pixel region used for imaging and a non-effective pixel region provided separately from the effective pixel region, wherein each pixel has an accumulation well which accumulates the photo-generated electric charges, a modulation transistor, and a transfer control element which transfers the photo-generated electric charges accumulated in the accumulation well to the modulation transistor, and when transferring the photo-generated electric charges accumulated in the accumulation well to the modulation transistor by the transfer control element, transfer of the photo-generated electric charges in the effective pixel region and the photo-generated electric charges which does not include the photo-generated electric charges in the effective pixel region is carried out separately at least two or more times.

A method of driving a solid state imaging device according to the present invent arranges, in a matrix form, a plurality of pixels that generate photo-generated electric charges corresponding to incidence light, and comprises an effective pixel region used for imaging and a non-effective pixel region provided separately from the effective pixel region, wherein an accumulation well that accumulates the photo-generated electric charges, a modulation transistor, and a transfer control element that transfers the photo-generated electric charges accumulated in the accumulation well to the modulation transistor are provided for each pixel, and when transferring the photo-generated electric charges accumulated in the accumulation well to the modulation transistor by the transfer control element, the method includes transferring the photo-generated electric charges in the effective pixel region and transferring the photo-generated electric charges that do not include the photo-generated electric charges in the effective pixel region.

According to such a structure, a solid state imaging device which reduces the maximum amount of current supply required for turning on the transfer transistor, and a method of driving the same can be realized.

Moreover, in the solid state imaging device according to the present invention, it is desirable that the transfer is carried out to regions that are divided into at least two in one axis direction of the matrix region which is two dimensional, and one region is a first region that includes the effective pixel region, and other region is a second region which does not include the effective pixel region.

Moreover, in the solid state imaging device according to the present invention, it is desirable that the photo-generated electric charges in the first region are batch transferred.

According to such a structure, the effective pixel region is batch transferred, therefore, the function of an electronic shutter is maintained, while the maximum amount of current supply required for turning on the transfer transistor can be reduced.

Moreover, in the solid state imaging device according to the present invention, it is desirable that the photo-generated electric charges in the second region are batch transferred.

Moreover, in the solid state imaging device according to the present invention, it is desirable that the second region includes an optical black region.

According to such a structure, the entire transfer period can be reduced while the function of an electronic shutter is maintained.

Moreover, in the solid state imaging device according to the present invention, it is desirable that the first region includes an optical black region and determines the black level based on the signal of the photo-generated electric charges in the optical black region.

According to such a structure, there will be no differences in the dark output between the effective pixel region and the non-effective pixel region which determines the black level, and, as a result, a good quality picture can be obtained.

### BRIEF DESCRIPTION OF THE DRAWINGS

FIG. 1 is a plan view showing the planar shape of a solid state imaging device of a first embodiment of the present invention.

FIG. 2 is a plan view showing the planar shape of one cell of FIG. 1.

FIG. 3 is a view explaining an effective pixel region and a non-effective pixel region.

FIG. 4 is a cross-sectional view showing the cross-section cut along the line A-A′ of FIG. 2.

FIG. 5 is a block diagram showing the entire structure of the element.

FIGS. 6A and B are equivalent circuit diagrams of a sensor cell.

FIG. 7 is a timing chart illustrating the outline of each driving period in the first embodiment.

FIGS. 8A-E are explanatory diagrams showing the potential relationship for each driving period.

FIG. 9 is an explanatory diagram showing changes of the driving voltage in each period in the driving sequence.

FIG. 10 is a timing chart showing a driving sequence.

FIGS. 11A and B are timing charts showing a driving sequence.

FIG. 12 is a view for explaining an effective pixel region and a non-effective pixel region in a modification.

FIG. 13 is a block diagram showing the entire structure of an element in the modification.

### DETAILED DESCRIPTION

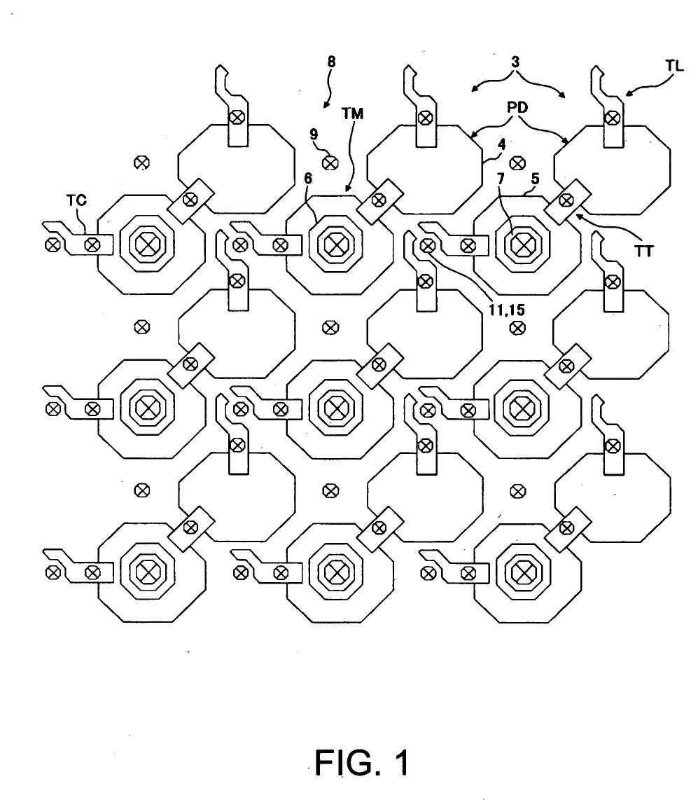

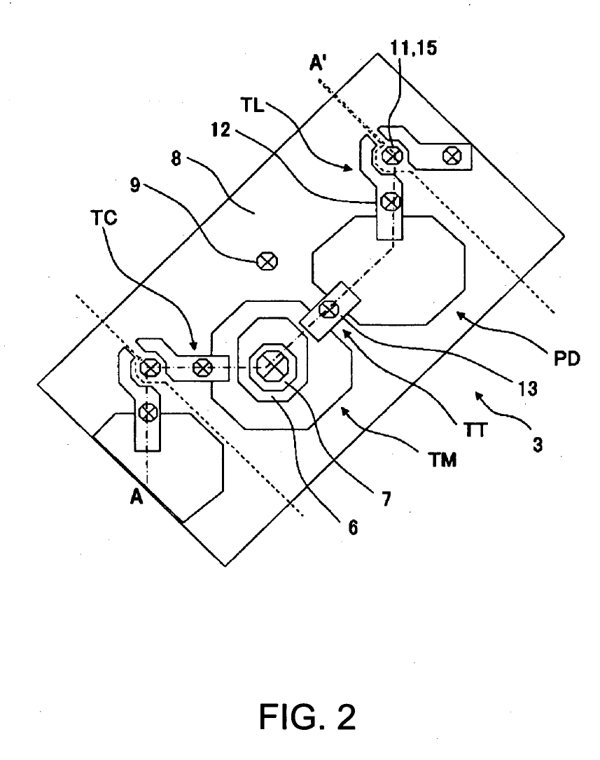

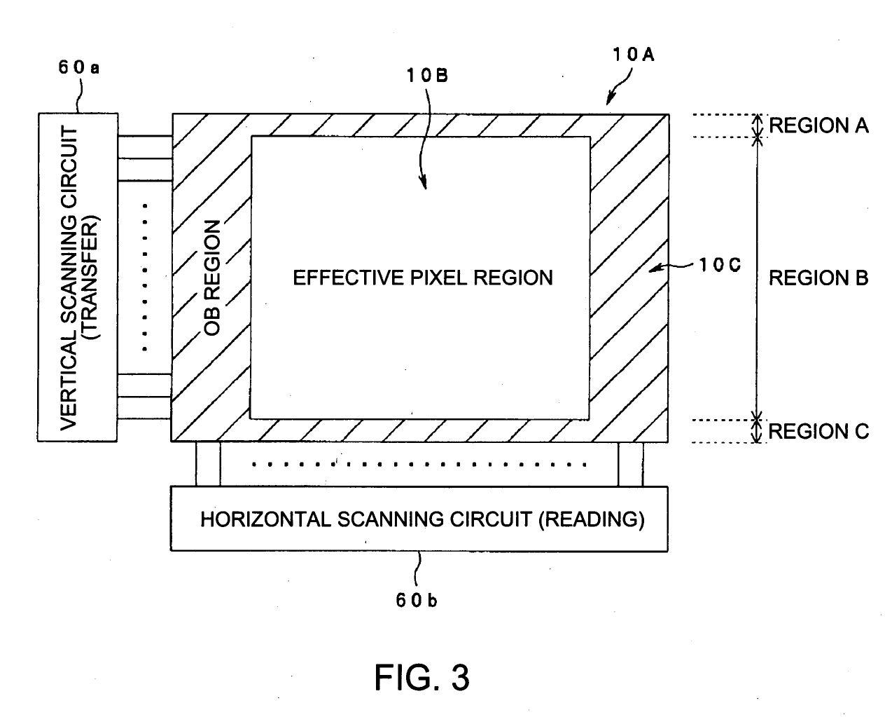

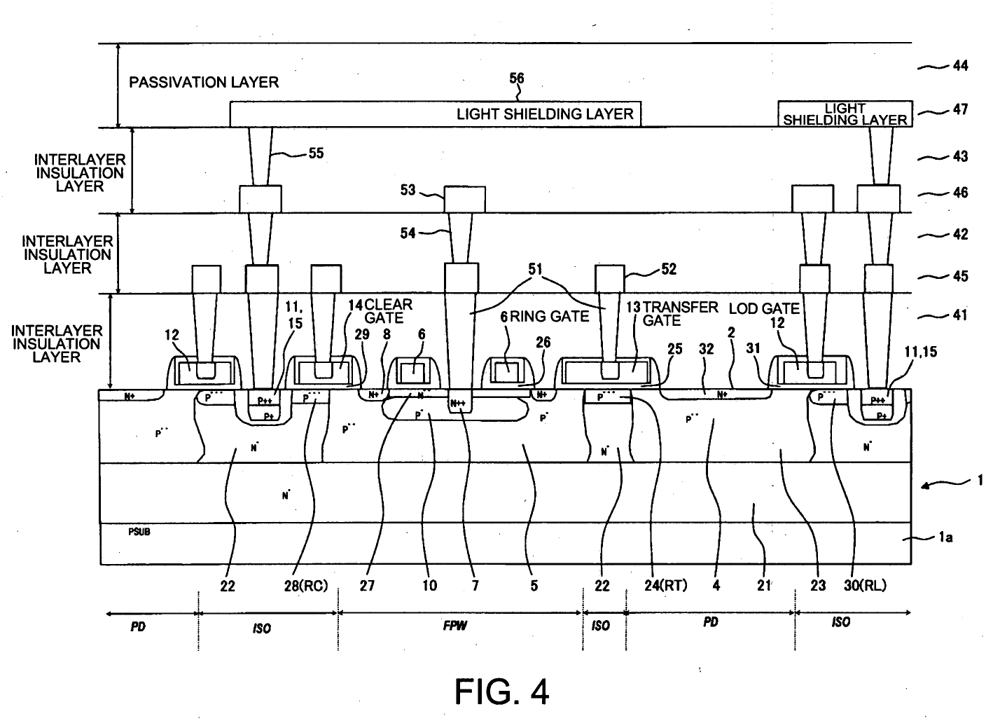

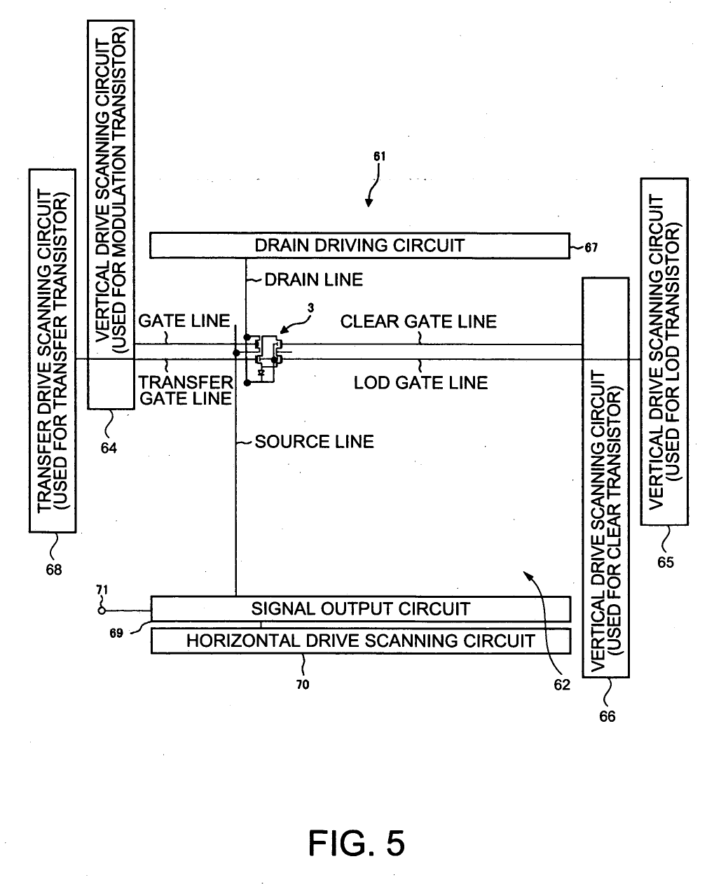

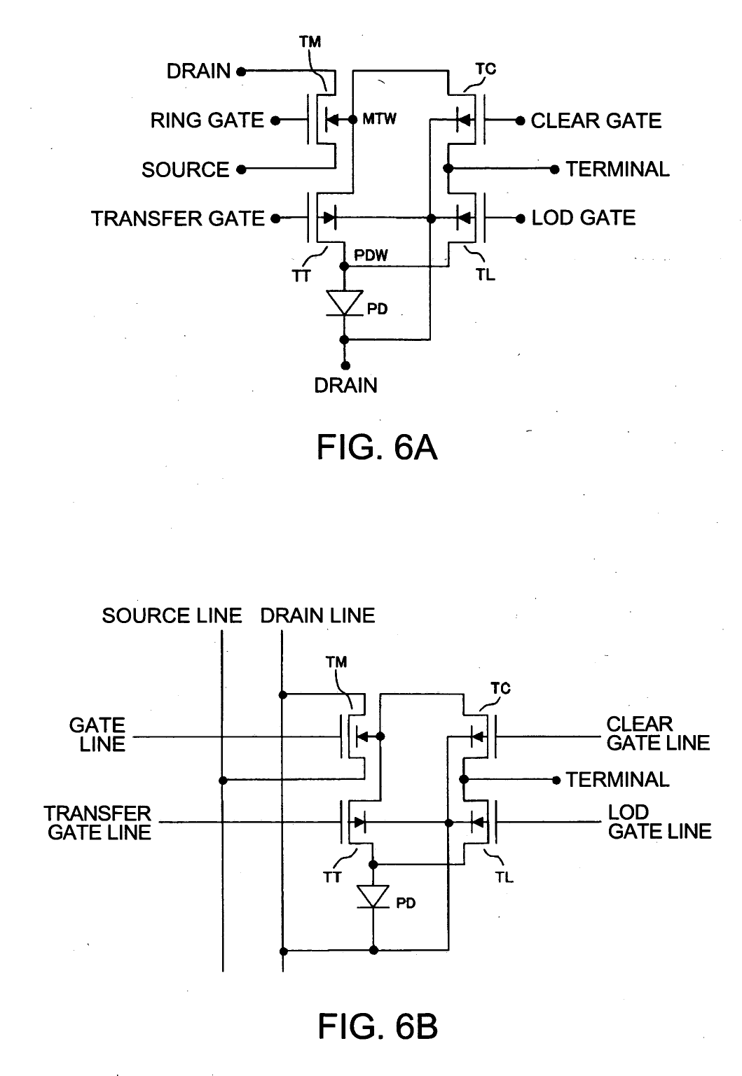

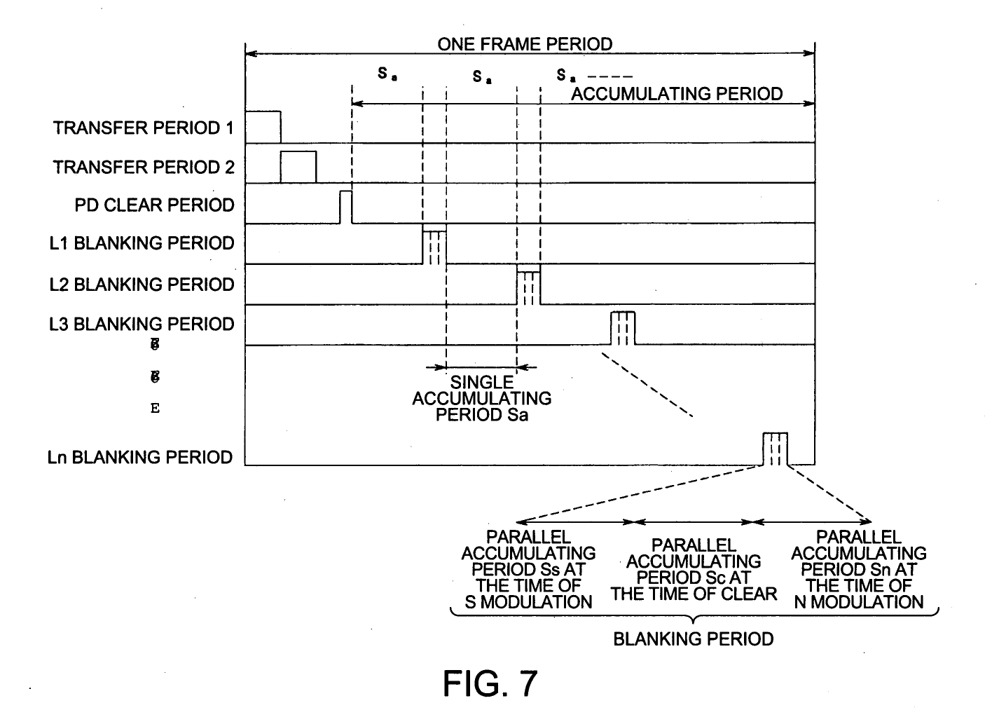

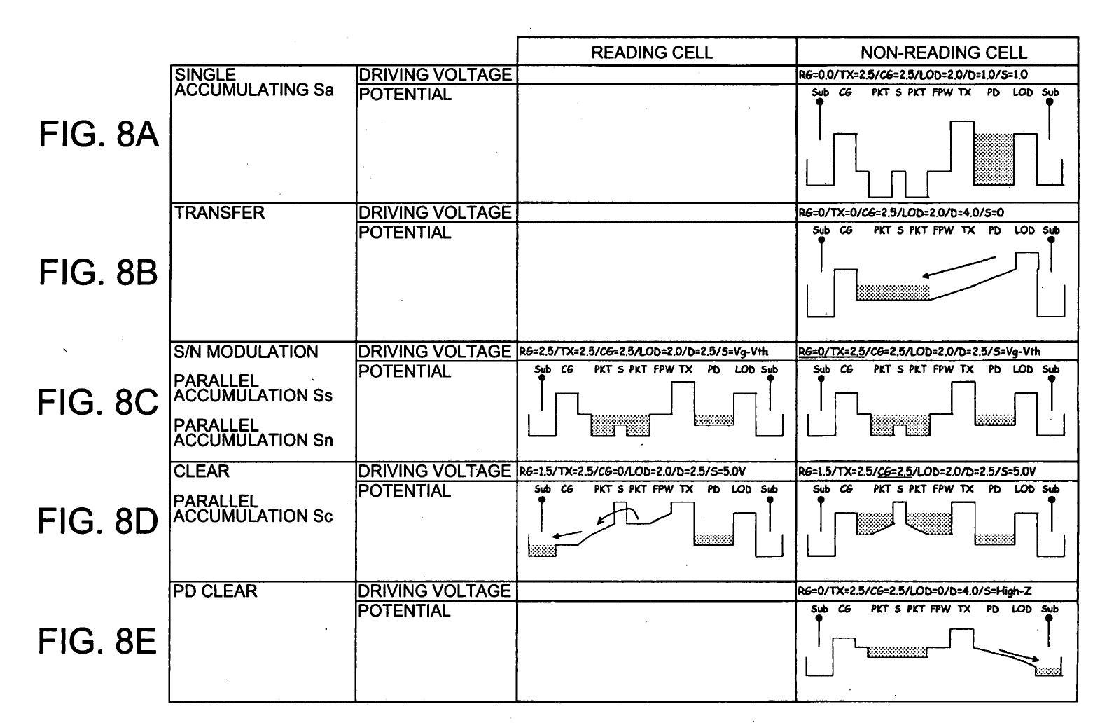

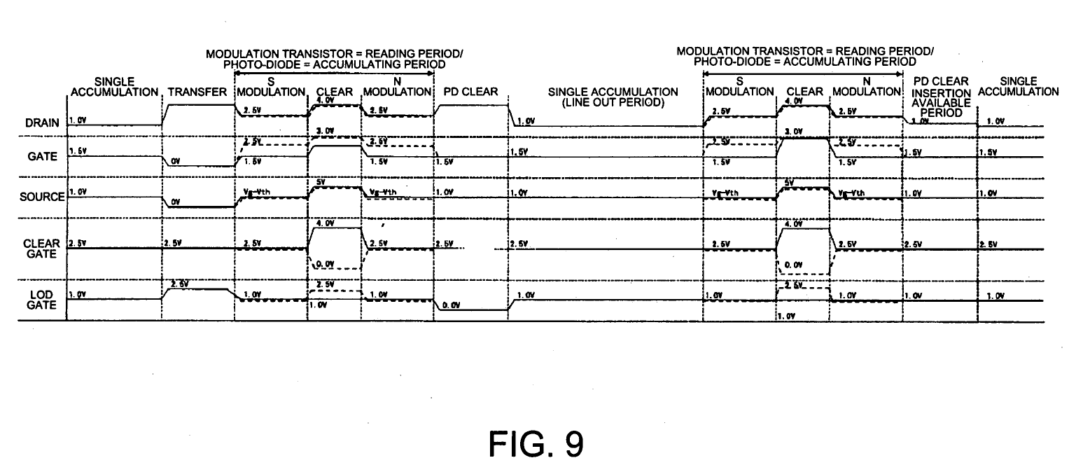

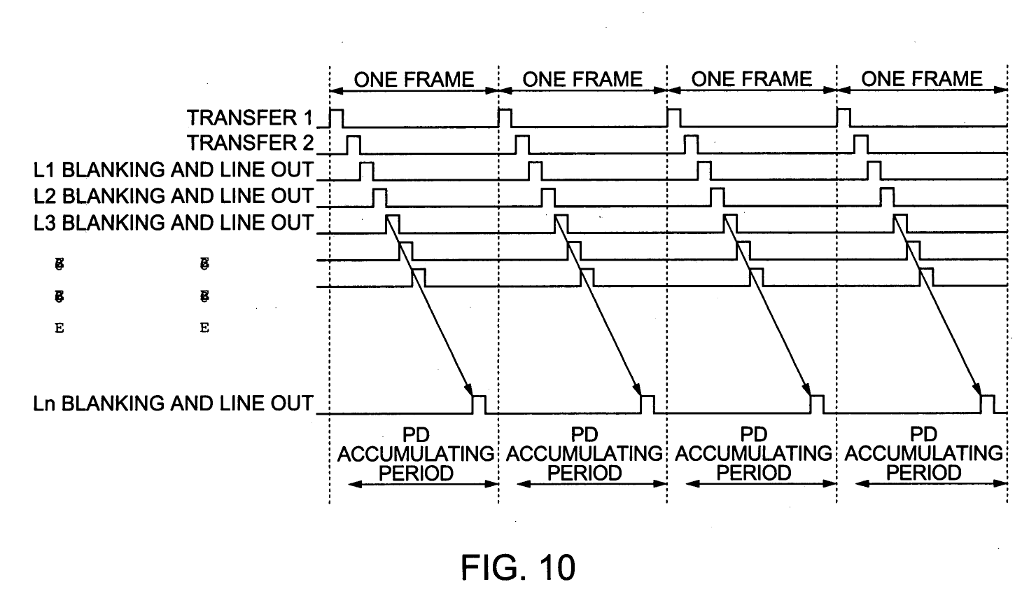

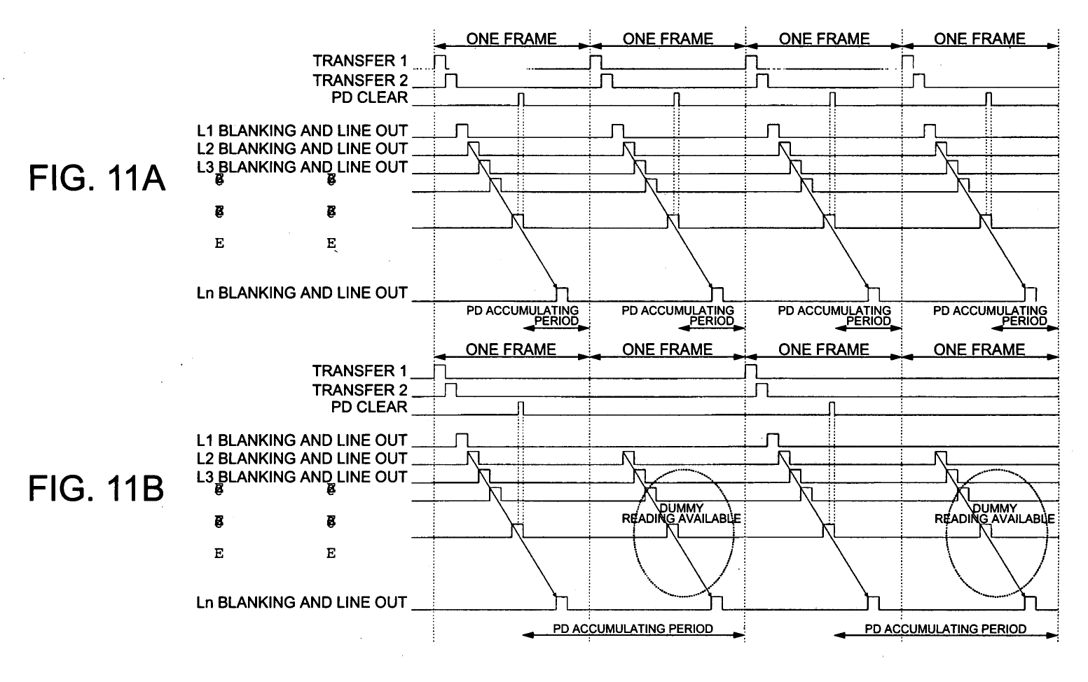

Hereinafter, embodiments of the present invention will be described in detail with reference to accompanying drawings. FIG. 1 through FIG. 11 are related to a first embodiment of the present invention, and FIG. 1 is a plan view showing the planar shape of a solid state imaging device of the present embodiment. FIG. 2 is a plan view showing the planar shape of one cell of FIG. 1. FIG. 3 is a view for explaining an effective pixel region and a non-effective pixel region. FIG. 4 is a cross-sectional view showing the cross section cut along the line A-A′ of FIG. 2. FIG. 5 is a block diagram showing the entire structure of an element, and FIG. 6 is an equivalent circuit diagram of a sensor cell. FIG. 7 is a timing chart for illustrating the outline of each driving period in the present embodiment. FIG. 8 is an explanatory diagram showing potential relationship for each driving period, and FIG. 9 is an explanatory diagram showing changes of the driving voltage for each period in the driving sequence. FIG. 10 and FIG. 11 are timing charts showing the driving sequences.

The solid state imaging device of the present embodiment includes a photoelectric conversion element, an accumulation well, a modulation well, and a modulation transistor. In the present embodiment, the photoelectric conversion element is a photo-diode. The accumulation well is provided in a photoelectric conversion element formation region, and accumulates electric charges (hereinafter, referred to as photo-generated electric charges) generated by the photoelectric conversion element. The modulation well is provided in the modulation transistor formation region, and stores the photo-generated electric charges transferred from the accumulation well. The threshold of the modulation transistor is modulated by the photo-generated electric charges stored in the modulation well, based on which the modulation transistor outputs the pixel signal.

Moreover, the solid state imaging device of the present embodiment includes a photo-generated electric charge transfer channel and a transfer control element. The photo-generated electric charge transfer channel is provided between the accumulation well and the modulation well. The photo-generated electric charges are transferred from the accumulation well to the modulation well through the photo-generated electric charge transfer channel. The transfer control element controls the potential barrier of the photo-generated electric charge transfer channel, and moves the photo-generated electric charges to the modulation well from the accumulation well. In the present embodiment, the transfer control element is a transfer transistor. The accumulation well and the modulation well are independently separated in terms of potential by the transfer control element. Accordingly, the accumulating period and the reading period (hereinafter, also referred to as the blanking period) can be set within the same period, and consequently the frame rate can be increased.

Furthermore, the solid state imaging device of the present embodiment includes a residual electric charge discharging channel, a contact region for discharging residual electric charges, and a residual electric charge discharging control element. The residual electric charge discharging channel is provided between the modulation well and the contact region for discharging residual electric charges, and is provided approximately horizontally along the substrate surface. The residual electric charge discharging channel is electrically coupled to a wiring layer provided on the substrate through the contact region for discharging residual electric charges. Electric charges remaining in the modulation well (hereinafter, referred to as residual electric charges) are transferred to the contact region for discharging residual electric charges from the modulation well through the residual electric charge discharging channel. The contact region for discharging residual electric charges is formed inside the residual electric charge discharging channel. The residual electric charge discharging control element controls the potential barrier of the residual electric charge discharging channel, and discharges the residual electric charges from the modulation well to the wiring layer. In the present embodiment, the residual electric charge discharging control element is a clear transistor. The residual electric charges are not directly discharged vertically downward to the substrate from the modulation well. That is, the residual electric charges are displaced approximately horizontally along the substrate surface, namely in the substrate lateral direction, and are then discharged to the wiring layer formed on the substrate. Accordingly, design flexibility of the potential in the modulation transistor formation region can be improved.

Furthermore, the solid state imaging device of the present embodiment includes an unwanted electric charge discharging channel, a contact region for discharging unwanted electric charges, and an unwanted electric charge discharging control element. The unwanted electric charge discharging channel is provided between the accumulation well and the contact region for discharging unwanted electric charges, and is provided approximately horizontally along the substrate surface. The unwanted electric charge discharging channel is electrically coupled to a wiring layer provided on the substrate through the contact region for discharging the unwanted electric charges. Electric charges that are unnecessary (hereinafter, referred to as unwanted electric charges), which overflow from the accumulation well without being accumulated in the accumulation well and do not contribute to the picture signal, are transferred to the contact region for discharging the unwanted electric charges from the accumulation well through the unwanted electric charge discharging channel. The contact region for discharging the unwanted electric charges is formed inside the unwanted electric charge discharging channel. The unwanted electric charge discharging control element controls the potential barrier of the unwanted electric charge discharging channel, and discharges unwanted electric charges from the accumulation well to the wiring layer. In the present embodiment, the unwanted electric charge discharging control element is a lateral-overflow-drain (hereinafter, referred to as LOD) transistor. The unwanted electric charges are not directly discharged vertically downward to the substrate from either one of the accumulation well and the contact region for discharging the unwanted electric charges. That is, the unwanted electric charges are displaced approximately horizontally along the substrate surface, namely in the substrate lateral direction, and are then discharged to the wiring layer formed on the substrate. Accordingly, miniaturization can be attained, even if the depth of the impurity layer in the photoelectric conversion element formation region is deepened to attain a higher quality picture.

According to the present embodiment, the unwanted electric charges accumulated in the accumulation well for initializing the accumulation are discharged through the contact region by using an LOD transistor. The setup in the unwanted electric charge discharging period between the blanking period for reading a predetermined line and the blanking period for reading the next line enables continuous imaging which does not produce delay at the output of the picture signal.

Structure of Sensor Cell

The solid state imaging device according to the present embodiment has a sensor cell array constituted by arranging sensor cells, which are unit pixels, in a matrix form, as will be described later. Each sensor cell accumulates photo-generated electric charges generated corresponding to incident light, and outputs the pixel signal with a level based on the accumulated photo-generated electric charges. The picture signal of one screen is obtained by arranging the sensor cells in a matrix form.

First, the structure of each sensor cell will be described with reference to FIG. 1 through FIG. 4. FIG. 1 shows a sensor cell with 3 horizontal pixels×3 perpendicular pixels, and FIG. 2 shows one sensor cell. In addition, one sensor cell is a region shown with the dashed lines of FIG. 2. In addition, the present embodiment shows an example using holes as the photo-generated electric charges. In the case of using electrons as the photo-generated electric charges, the same can be constructed. FIG. 3 is a view for explaining an effective pixel region and a non-effective pixel region. Moreover, FIG. 4 shows a cross-sectional structure of the cell cut along the line A-A′ of FIG. 2.

As shown in the plan views of FIG. 1 and FIG. 2, a photo-diode PD and a modulation transistor TM are adjacently formed in a sensor cell 3 which is a unit pixel. As for the modulation transistor TM, an N channel depletion MOS transistor is used, for example. The unit pixel has an almost rectangular shape, each side of which is inclined to the row or the line direction of the sensor cell array.

In a photo-diode PD formation region (PD of FIG. 4), which is a photoelectric conversion element formation region, an opening region 2 is formed on the surface of the substrate 1, and an accumulation well 4, which is a P type well with a region wider than the opening region 2, is formed in the relatively shallow position of the substrate 1 surface. A modulation well 5 which is a P type well is formed in a modulation transistor TM formation region (FPW of FIG. 4) with a predetermined space apart from the accumulation well 4.

On the modulation well 5, a ring-shaped gate (ring gate) 6 is formed in the substrate 1 surface, and a source region 7 which is a high concentration N type region is formed in the region near the substrate 1 surface of the center opening portion of the ring gate 6. An N type drain region 8 is formed in the surroundings of the ring gate 6. A drain contact region 9 of an N⁺ layer is formed in a predetermined position of the drain region 8 near the substrate 1 surface.

The modulation well 5 controls the threshold voltage of the channel of the modulation transistor TM. In the modulation well 5, a carrier pocket 10 (FIG. 4) which is a P type high concentration region is formed under the ring gate 6. The modulation transistor TM is constituted by the modulation well 5, the ring gate 6, the source region 7, and the drain region 8, and the threshold voltage of the channel changes corresponding to the electric charges accumulated in the modulation well 5 (carrier pocket 10).

A depletion region (not shown) is formed in the boundary region, which will be described later, of an N type well 21, and a P type accumulation well 4 that are formed on the substrate 1 under the opening region 2 of the photo-diode PD, and photo-generated electric charges generated by incident light through the opening region 2 are generated in the depletion region. In the present embodiment, the photo-generated electric charges generated are accumulated in the accumulation well 4.

The electric charges accumulated in the accumulation well 4 are transferred to the modulation well 5, and are stored in the carrier pocket 10. Accordingly, the source potential of the modulation transistor TM becomes the one corresponding to the amount of the electric charges transferred to the modulation well 5, i.e., to the incident light upon the photo-diode PD.

A contact region (hereinafter, referred to as OD contact region) 11 for discharging unwanted electric charges that do not contribute to the picture signal, including the electric charges that overflow from the accumulation well 4, out of the photo-generated electric charges accumulated in the accumulation well 4, is formed by a high concentration P type diffusion layer in the substrate 1 surface near the accumulation well 4. On the substrate 1 surface between the OD contact region 11 and the accumulation well 4 region, an LOD gate 12 of a lateral over flow drain (hereinafter, referred to as LOD) transistor TL for forming a channel RL for the unwanted electric charges (hereinafter, referred to as unwanted electric charge discharging channel) including the electric charges that overflow between the OD contact region 11 and the accumulation well 4 region is formed. In addition, two-dimensionally, one end of the LOD gate 12 hangs over the accumulation well 4 region.

By providing the LOD transistor TL as an unwanted electric charge discharging control element, the potential barrier between the OD contact region 11 and the accumulation well 4 can be controlled, and thus the unwanted electric charges can be discharged through the wiring on the substrate from the OD contact region 11 through the LOD transistor TL.

In the present embodiment, a transfer transistor TT as the transfer control element is formed between the accumulation well 4 and the modulation well 5. The transfer gate 13 of the transfer transistor TT is formed on the substrate 1 surface of a channel RT between the accumulation well 4 and the modulation well 5 (hereinafter, simply referred to as transfer channel). The electric charge transfer from the accumulation well 4 to the modulation well 5 can be controlled by controlling the potential barrier of the transfer channel RT by the transfer transistor TT.

Moreover, in the present embodiment, in the substrate surface near the modulation well 5, a contact region 15 for discharging by a high concentration P type diffusion layer (hereinafter, referred to as discharging contact region) is formed. On the substrate 1 surface between the discharging contact region 15 and the modulation well 5 region, a clear gate 14 of a clear transistor TC for controlling the potential barrier of the channel RC between the discharging contact region 15 and the modulation well 5 region (hereinafter, referred to as residual electric charge discharging channel) is formed. In addition, as for the clear gate 14, one end thereof two-dimensionally hangs over the modulation well 5 region.

Moreover, as shown in FIG. 3, the solid state imaging device has an imaging face 10A where a plurality of sensor cells 3 are arranged in a matrix form. The imaging face 10A is divided into an effective pixel region 10B used for imaging and a non-effective pixel region 10C (shaded portion) to the outside of the effective pixel region 10B. The non-effective pixel region 10C is the so-called optical black region, and is the region used for judging black color. The picture signal of each sensor cell is read by a vertical scanning circuit 60a and a horizontal scanning circuit 60bB. In FIG. 3, it is divided into at least three in one axis direction of the matrix region which is two dimensional. One is a region B including the effective pixel region 10B, and other two are regions A and C including only the non-effective pixel which do not include the effective pixel region 10B. The structures of the vertical scanning circuit 60a and the horizontal scanning circuit 60b in FIG. 3 will be described later.

Cross-Section of Sensor Cell

Furthermore, with reference to FIG. 4, the cross-sectional structure of the sensor cell 4 will be described in detail. Incidentally, the subscripts, “⁻” and “⁺”, of N and P in FIG. 3 indicate the state from a portion with lighter impurity concentration (subscript ⁻⁻⁻) to a heavier impurity concentration (subscript ⁺⁺⁺), depending on the number of the subscript.

FIG. 4 shows one unit pixel (cell) and a photo-diode PD formation region (PD) of a pixel adjacent to this cell. One cell includes the photo-diode PD formation region (PD) and the modulation transistor TM formation region (FPW). An isolation region (ISO) is formed between the photo-diode PD formation region and the modulation transistor TM formation region in the cell and between adjoining cells.

The N type well 21 of N⁻ is formed at a relatively deep position of the substrate 1 in the entire area of P type substrate 1a. An isolation region 22 used for isolating elements by an N⁻ layer is formed on the N type well 21. On the N type well 21, a P⁻⁻ layer 23 is formed in the entire element excluding the isolation region 22.

The P⁻⁻ layer 23 in the photo-diode PD formation region functions as the accumulation well 4. The P⁻⁻ layer 23 in the modulation transistor TM formation region functions as the modulation well 5, and in the modulation well 5, the carrier pocket 10 is formed by a P⁻ diffusion.

The transfer transistor TT is formed on the substrate surface side in the isolation region 22 between the photo-diode PD formation region and the modulation transistor TM formation region in the cell. The transfer transistor TT is constituted by forming a P⁻⁻⁻ diffusion layer 24, which constitutes a channel on the substrate surface, and by forming the transfer gate 13 on the substrate surface through a gate insulation layer 25. The P⁻⁻⁻ diffusion layer 24, being coupled to the accumulation well 4 and the modulation well 5, constitutes the transfer channel RT, and the potential barrier of the transfer channel RT is controlled corresponding to the applied voltage to the transfer gate 13.

In the modulation transistor TM formation region, the ring gate 6 is formed in the substrate surface through a gate insulation layer 26, and an N⁻⁻ diffusion layer 27 which constitutes a channel is formed in the substrate surface under the ring gate 6. An N⁺⁺ diffusion layer is formed in the substrate surface of the center of the ring gate 6 to constitute the source region 7. Moreover, an N⁺ diffusion layer is formed in the substrate surface in the periphery of the ring gate 6 to constitute the drain region 8. The N⁻⁻ diffusion layer 27 which constitutes a channel is coupled to the source region 7 and the drain region 8.

A discharging contact region 15 and an OD contact region 11 are formed, at the substrate surface side, in the isolation region 22 between the photo-diode PD formation region and the modulation transistor TM formation region of adjoining cells. In the present embodiment, the discharging contact region 15 and the OD contact region 11 are combined to be used; however, these may be constructed separately. The discharging and the OD contact regions, 15 and 11, are obtained by forming a P⁺⁺ diffusion layer in the substrate surface.

Then, the clear transistor TC is formed at the substrate surface side between the modulation transistor TM formation region, and the discharging and OD contact regions 15 and 11. The clear transistor TC is constituted by forming a P⁻⁻⁻ diffusion layer 28 which constitutes a channel in the substrate surface between the modulation transistor TM formation region, and the discharging and OD contact regions 15 and 11, and by forming the clear gate 14 in the substrate surface through a gate insulation layer 29. The P⁻⁻⁻ diffusion layer 28, being coupled to the modulation well 5 and the discharging and OD contact regions 15 and 11, constitutes the residual electric charge discharging channel RC, and the potential barrier of the residual electric charge discharging channel RC is controlled corresponding to the applied voltage to the clear gate 14.

The LOD transistor TL is formed at the substrate surface side between the photo-diode PD formation region, and the discharging and OD contact regions 15 and 11. The LOD transistor TL is constituted by forming a P⁻⁻⁻ diffusion layer 30 which constitutes a channel in the substrate surface between the photo-diode PD formation region, and the discharging and OD contact regions 15 and 11, and by forming the LOD gate 12 through a gate insulation layer 31 in the substrate surface. The P⁻⁻⁻ diffusion layer 30, being coupled to the accumulation well 4 and the discharging and OD contact regions 15 and 11, constitutes the unwanted electric charge discharging channel RL, and the potential barrier of the unwanted electric charge discharging channel RL is controlled corresponding to the applied voltage to the LOD gate 12.

In addition, an N⁺ diffusion layer 32, as a pinning layer, is formed at the substrate surface side of the photo-diode PD formation region.

A lower layer wiring layer 45 is formed in the substrate surface through an interlayer insulation layer 41, and an upper layer wiring layer 46 is formed through an interlayer insulation layer 42 on the lower layer wiring layer 45. Furthermore, on the upper layer wiring layer 46, a light shielding layer 47 is formed through an interlayer insulation layer 43, and a passivation layer 44 is formed on the light shielding layer 47. The clear gate 14, the LOD gate 12, the transfer gate 13, the discharging and OD contact regions 15 and 11, and the source region 7 are electrically coupled to each wiring 52 of the lower layer wiring layer 45 through a contact hole 51 opened in the interlayer insulation layer 41. In addition, each of the wirings 52 and 53 of the lower layer and of the upper layer wiring layers 45 and 46 is made of metal material, such as aluminum.

Furthermore, each wiring 52 of the lower layer wiring layer 45 and each wiring 53 of the upper layer wiring layer 46 are electrically coupled through a contact hole 54 formed in the interlayer insulation layer 42. Moreover, in the interlayer insulation layer 43, a contact hole 55 for coupling a light shielding layer 56 formed in the light shielding layer 47 and one wiring of the upper layer wiring layer 46 is opened, and the discharging and OD contact regions 15 and 11 are coupled to the light shielding layer 56 through the lower layer and the upper layer wiring layers 45 and 46.

In the present embodiment, the transfer transistor TT, the clear transistor TC, and the LOD transistor TL are controlled independently, and then the potential barriers of the transfer channel RT, the residual electric charge discharging channel RC and the unwanted electric charge discharging channel RL are controlled. When describing the ups and downs (raising and lowering) of the potential of these channels, RT, RC and RL with reference to the hole potential, in the accumulating period, the potentials of the transfer channel RT, the residual electric charge discharging channel RC and the unwanted electric charge discharging channel RL are set high enough to allow the photo-generated electric charges (in case of holes) to be accumulated, while the potentials of the residual electric charge discharging channel RC and the unwanted electric charge discharging channel RL are set lower than the potential of the transfer channel RT. In addition, hereinafter, the raising and lowering of the potential will be described with reference to the potential of holes, not to the potential of electrons.

Moreover, the structure of each sensor cell in the effective pixel region 10B of FIG. 3 is as shown in FIG. 4, however, in the non-effective pixel region 10C of FIG. 3, i.e., the optical black region, the light-shielding layer 56 formed in the light shielding layer 47 is formed all over the non-effective pixel region 10C as to cover the photo-diode formation region (PD). Then, the output signal of the sensor cell 3 in the non-effective pixel region 10C is used for judging black color.

Circuit Configuration of the Entire Device

Next, the circuit configuration of the entire solid state imaging device according to the present embodiment will be described with reference to FIG. 5.

A solid state imaging device 61 has a sensor cell array 62 including the sensor cell 3 of FIG. 2, and circuits 64 through 70 which drive each sensor cell 3 in the sensor cell array 62. The sensor cell array 62 is constituted by arranging the cell 3 in a matrix form. The sensor cell array 62 includes a plurality of sensor cells 3 in the effective pixel region 10B of 640×480, and a plurality of sensor cells 3 in the region (OB region) of the optical black (OB) which is the non-effective pixel region 10C to the outside of the effective pixel region 10B as shown in FIG. 3. If the OB region is included, the sensor cell array 62 is composed of sensor cells 3 of 712×500, for example.

Equivalent Circuit of Sensor Cell

FIG. 6 shows a specific circuit configuration of each sensor cell in FIG. 5. FIG. 6A shows an equivalent circuit of the sensor cell and FIG. 6B shows the coupling between the sensor cell and each signal line.

Each sensor cell 3 includes the photo-diode PD which carries out photoelectric conversion, the modulation transistor TM for detecting the optical signal and reading, and the transfer transistor TT which controls transfer of photo-generated electric charges. The photo-diode PD generates the electric charges (photo-generated electric charges) corresponding to incident light, and accumulates the generated electric charges in the accumulation well 4 (corresponding to a coupling point PDW in FIG. 6). The transfer transistor TT transfers the photo-generated electric charges accumulated in the accumulation well 4 in the accumulating period to the carrier pocket 10 in the modulation well 5 (corresponding to a coupling point MTW in FIG. 6) used for the threshold modulation of the modulation transistor TM in the transfer period, and stores.

With respect to the modulation transistor TM, that the photo-generated electric charges are stored in the carrier pocket 10 is equivalent to that the back gate bias thereof is changed, and the threshold voltage of the channel changes corresponding to the amount of the electric charges in the carrier pocket 10. Accordingly, the source voltage of the modulation transistor TM becomes the one corresponding to the electric charges in the carrier pocket 10, i.e., the brightness of incident light upon the photo-diode PD.

Between the modulation well 5 and a terminal, the clear transistor TC as the residual electric charge discharging control element is arranged. The clear transistor TC controls the potential barrier between the modulation well 5 and the terminal, and discharges the electric charges remaining in the modulation well 5 of the cell 3, after completion of the reading of the pixel signal. On the other hand, between the accumulation well 4 and the terminal, an LOD transistor TL as the unwanted electric charge discharging control element is arranged. The LOD transistor TL controls the potential barrier between the accumulation well 4 and the terminal, and discharges the unwanted electric charge in the accumulation well 4 to the terminal.

Thus, each cell 3 exhibits operations of accumulation, transfer, reading, and discharging or the like by applying a driving signal to the ring gate 6, the source and the drain of the modulation transistor TM, the transfer gate 13 of the transfer transistor TT, the clear gate 14 of the clear transistor TC, and the LOD gate 12 of the LOD transistor TL. As shown in FIG. 5, a signal is provided to each portion of the cell 3 from vertical drive scanning circuits 64 through 66, a drain driving circuit 67, and a transfer drive scanning circuit 68. The blanking means, the accumulation clear means, and the transfer means are constituted by these vertical drive scanning circuits 64 through 66, the drain driving circuit 67, and the transfer drive scanning circuit 68.

FIG. 6B shows, with respect to one cell of the cells 3 arranged in a matrix form, the coupling to each of the scanning circuits 64 through 66, each of the driving circuits 67 and 68, and the signal output circuit 69. The coupling condition for other cells is the same. Each cell 3 is provided corresponding to the intersection of a plurality of source lines arranged in the horizontal direction and a plurality of gate lines arranged in the vertical direction with respect to the sensor cell array 62. In each cell 3 of each line arranged in the horizontal direction, the ring gate 6 of the modulation transistor TM is coupled to a common gate line, and in each cell 3 of each row arranged in the vertical direction, the source of the modulation transistor TM is coupled to a common source line.

By providing an ON signal to one of the plurality of gate lines, each cell commonly coupled to the gate line to which the ON signal is provided is simultaneously selected, and the pixel signal is outputted through each source line from each source of these selected cells. The vertical drive scanning circuit 64 provides an ON signal to the gate line by sequentially shifting in one frame period. The pixel signal from each cell of the line to which the ON signal is provided is simultaneously read from the source line by one line portion, and is provided to the signal output circuit 69. The pixel signal for one line portion is sequentially outputted (line-out) for every pixel from the signal output circuit 69 by the horizontal drive scanning circuit 70.

In the present embodiment, the accumulation well 4 and the modulation well 5 are formed independently and separately in terms of the potential, and the transfer transistor TT which controls the potential barrier between the accumulation well 4 and the modulation well 5 can simultaneously implement the accumulation of the photo-generated electric charges by the photo-diode PD, and the reading of the pixel signal by the modulation transistor TM. Control of the transfer transistor TT is carried out by providing a gate signal to the transfer gate 13 of each transfer transistor TT from the transfer drive scanning circuit 68. Control of the transfer transistor TT to the effective pixel region 10B and the non-effective pixel region 10C is carried out so as not to batch-transfer all the pixels, as will be described later.

Moreover, in the present embodiment, as described above, the unwanted electric charge discharging channel RL of the accumulation well 4 and the residual electric charge discharging channel RC from the modulation well 5, which are adjacently arranged, are set to mutually different channels. Then, by providing the LOD transistor TL and the clear transistor TC which control the potential barrier of these two channels, respectively, discharging of the unwanted electric charge from the accumulation well 4 and discharging of the residual electric charge from the modulation well 5 can be surely carried out in terms of potential. Control of the LOD transistor TL and the clear transistor TC is carried out by providing a gate signal to each of the LOD gate 12 or the clear gate 14 from the vertical drive scanning circuits 65 and 66, respectively. In addition, the drain driving circuit 67 provides a drain voltage to the drain of each modulation transistor TM.

Relationship between transfer period, accumulating period, and reading period

FIG. 7 is a timing chart for illustrating each driving period in the present embodiment. In addition, FIG. 7 shows the driving sequence in the normal mode. In FIG. 7, L1, L2 and so on correspond to each line of the sensor cell array 62.

The accumulating period is set to a period common to all the cells, as will be described later. However, reading is carried out for each line. The reading timing differs for each line, and the reading period (hereinafter, referred to as blanking period) for each line is shown as a pulse shape in FIG. 7.

Transfer Period

First, the transfer period is described. FIG. 7 shows the timing for each period in one frame. The transfer period includes at least two transfer periods, i.e., a transfer period 1, and a transfer period 2. In the imaging face 10A shown in FIG. 3, when the region including the effective pixel region 10B and the region of only the non-effective pixel region 10C are divided in one axis direction of the two dimensional matrix region, for example, in the vertical direction (FIG. 3), the region is divided into the region B including the effective pixel region 10B and two regions A and C of only the non-effective pixel region 10C, as shown in FIG. 3. The region B also includes the sensor cell of the non-effective pixel region 10C.

In the transfer period 1, the pixel signal of all the sensor cells in the region B is batch transferred to the modulation well 5 from the accumulation well 4 by simultaneously providing the gate signal from the transfer drive scanning circuit 68 to the transfer gate 13 of each transfer transistor TT in the region B.

In the transfer period 2, the pixel signal of all the sensor cells in the regions A and C are batch transferred to the modulation well 5 from the accumulation well 4 by simultaneously providing the gate signal to the transfer gate 13 of each transfer transistor TT in the regions A and C from the transfer drive scanning circuit 68. Accordingly, the pixel signal of a plurality of sensor cells in the imaging face 10A are not batch-transferred for all the pixels, but are transferred separately at two times.

Thus, the pixel signal of all the sensor cells in the effective pixel region 10B is batch transferred, therefore the so-called electronic shutter function is maintained, and the pixel signal of the sensor cell in the region which includes the optical black region is batch transferred at a separate timing, and thereby the amount of the current required for the transfer is reduced.

By separating the region A and the region C, the gate signal from the transfer drive scanning circuit 68 is simultaneously provided to the transfer gate 13 of each transfer transistor TT of the region A, and to the transfer gate 13 of each transfer transistor TT of the region C in the other timing, and thus the pixel signal of all the sensor cell of each of the region A and C may be transferred from the accumulation well 4 to the modulation well 5.

Reading Period

In the present embodiment, the reading period (blanking period) comprises an S (signal) modulation period, a clear period, and an N (noise) modulation period. A signal component and a noise component are read from the same cell and compared to remove the variation between cells 3 and various kinds of noises. During the S modulation period, an S modulation operation for reading the pixel signal based on the photo-generated electric charges accumulated in the modulation well 5 is carried out. During the clear period, a clear operation for discharging the photo-generated electric charge remaining in the modulation well 5 through the residual electric charge discharging channel RC is carried out in order to read the noise component. During the N modulation period, in order to read the noise component from the modulation well 5, an N modulation operation, which reads the pixel signal after the clear, is carried out.

Accumulating Period

In the present embodiment, a provision is made to carry out the accumulation operation (parallel accumulation operation) to the accumulation well 4 even in the blanking period. Namely, the S modulation period, the clear period, and the N modulation period during the blanking period, are made, in terms of the accumulation, a parallel accumulating period Ss at the time of the S modulation, the parallel accumulating period Sc at the time of the clear, and a parallel accumulating period Sn at the time of the N modulation, respectively.

The accumulating period according to the present embodiment includes, besides a parallel accumulating period which is the same period as the blanking period, a single accumulating period Sa where a single accumulation operation is carried out. The pixel signal read in the blanking period is stored in a line memory (corresponding to the signal output circuit 69 of FIG. 5). The pixel signal for one line portion is sequentially outputted per one pixel from this line memory, and the reading from each cell of the following line is carried out after the output of the line memory is completed. Therefore, the reading from the cell of the following line cannot be carried out until the output from the line memory is completed, and thus the single accumulating period Sa is set to a period (hereinafter, referred to as line-out period) required to transfer and output (line-out) the pixel signal from such a line memory.

In the present embodiment, although the illustration is omitted in FIG. 7, a provision is made to provide, even in the line-out period, a PD clear period (accumulation initialization period) which carries out a PD clear which is the accumulation initialization processing, as will be described later. In addition, the PD clear is the process of discharging the unwanted electric charges in the accumulation well 4, i.e., the process of initializing the accumulation, and determining the start timing of the accumulating period.

Sequence in Frame

In the present embodiment, for example, as shown in FIG. 7, one frame period is constituted by cyclically repeating the single accumulating period Sa (same period as the line out period) and the parallel accumulating periods Ss, Sc, and Sn (same period as the blanking period), after the transfer period and the PD clear period, as will be described later. All the cells 3 of the sensor cell array 62 cyclically repeat operations of the single accumulating period Sa and the parallel accumulating periods Ss, Sc, and Sn. Then, only the period shown in the pulse shape of FIG. 7 among the parallel accumulating periods Ss, Sc, and Sn is set in the blanking period for each line, and the reading operation is carried out. In one frame period, the single accumulating period Sa and the blanking period are repeated a number of times based on the number of lines.

Namely, one frame period has a blanking period of a number of the lines, and each line is designated respectively to the line (hereinafter, referred to as reading line) in which a reading of just one blanking period is carried out during one frame period. Each cell in the reading line is called a reading cell. Moreover, a line other than the reading line is called a non-reading line, and each cell in the non-reading line is called a non-reading cell.

In the single accumulating period Sa and the parallel accumulating periods Ss, Sc, and Sn, the photo-generated electric charges are successively accumulated in the accumulation well 4, as will be described later. As shown in FIG. 7, the time period from completion of the PD clear period to the completion of the frame period occurring before the blanking period is the accumulating period, during which the photo-generated electric charges accumulated in the accumulation well 4 at this period will be transferred from the accumulation well 4 to the modulation well 5 during the transfer period, which is the leading period of the following frame, shown in FIG. 7, and are stored. During the transfer period, the batch-transfer operation is not carried out to all the cells, but, as described above, the pixel signal of a plurality of sensor cells in the imaging face 10A is transferred separately at two times.

Next, the PD clear period, which is very short, is set up in order to discharge the photo-generated electric charges generated from the completion of the transfer period to the start of the accumulating period. In the PD clear period, unwanted electric charges are discharged from the accumulation well 4 of all the cells. In addition, the PD clear period is used for setting up the length of the accumulating period, and the PD clear period can be omitted in the normal mode. Accordingly, it is not necessary to set up the PD clear period in the line-out period in the normal mode.

Looking at a predetermined line, for example, in each cell in a line L1, as the reading cell, at the modulation transistor TM side during the blanking period as shown in FIG. 7, the S modulation operation, the clear operation, and the N modulation operation are carried out. At the same time, at the accumulation well 4 side, the parallel accumulation operation Ss at the time of the S modulation, the parallel accumulation operation Sc at the time of the clear, and the parallel accumulation operation Sn at the time of the N modulation are carried out. Each cell of the line L1, during the period other than this blanking period, as the non-reading cell, cyclically repeats the single accumulation operation Sa, the parallel accumulation operation Ss at the time of the S modulation, the parallel accumulation operation Sc at the time of the clear, and the parallel accumulation operation Sn at the time of the N modulation.

Namely, any cell, during all the periods excluding the transfer period and the PD clear period, is set in the single or the parallel accumulating period, and especially in the blanking period of the reading cell, the parallel accumulation operation is carried out. Then, the accumulated photo-generated electric charges are transferred, specifically being divided in two transfer periods, to the modulation well 5 in the leading transfer period of the following frame. Namely, the period from the completion of the PD clear period (the completion of the transfer period in case that the PD clear period is omitted) of the preceding frame to the start of the transfer period is the accumulating period for each cell, and the pixel signal used for blanking is based on the photo-generated electric charges accumulated in the accumulating period of the preceding frame.

Potential

Next, with reference to FIG. 8, operations in the single accumulating period Sa, the transfer period, the S modulation period (parallel accumulating period Ss), the clear period (parallel accumulating period Sc), and the N modulation period (parallel accumulating period Sn) and the PD clear period will be described based on the potential relationship. FIG. 8 is a diagram illustrating the potential relationship for each period, with the direction, where the hole potential becomes high, being a positive side. FIG. 8A shows the condition at the time of the single accumulation, FIG. 8B shows the condition at the time of the transfer, FIG. 8C shows the condition at the time of the S modulation or the N modulation (S/N modulation), FIG. 8D shows the condition at the time of the clear and FIG. 8E shows the condition at the time of the clear (PD clear) of the accumulation well 4 in a high-speed shutter mode. The column on the left side of FIG. 8 shows the condition of the reading cell, and the column on the right side shows the condition of the non-reading cell. In addition, FIG. 8 shows the potential changes based on the electric charges, with a satin pattern. Moreover, as described above, whether each cell becomes either the reading cell or the non-reading cell is indicated by the pulse of FIG. 7.

Moreover, FIG. 9 shows changes of the driving voltage in each period. FIG. 9 shows changes of the driving voltage in each period, and the actual driving sequence and the order of the period to set differ. FIG. 9 shows the setup of the driving voltage shown in FIG. 8 in time order. In addition, as for the blanking period, in FIG. 9, the driving voltage of the reading cell is shown with the dashed line and the driving voltage of the non-reading cell is shown with the solid line.

FIG. 8 shows the potential relationship at each position, taking the position corresponding to the cutting line of each cell of FIG. 2 in the horizontal axis, and taking the potential with reference to the hole in the vertical axis. From the left side toward the right side in FIG. 8, the potentials in the substrate at the positions of the discharging contact region (Sub), the clear gate (CG) 14 (residual electric charge discharging channel portion), one end of the carrier pocket (PKT) 10, the source (S), the other end of the carrier pocket (PKT) 10, the transfer gate (TX) 13 (transfer channel RT portion), the accumulation well region (PD), the LOD gate (LOD) 12 (unwanted electric charge discharging channels RL portion) and the OD contact region (substrate) are shown.

The potential of each portion changes corresponding to the driving voltage. For example, if the source voltage and the drain voltage or the like are increased or decreased, the potential of the surroundings will increase or decrease as well. For example, the potential of the accumulation well 4 is influenced mainly by both the applied voltages to the source and to the drain of the modulation transistor TM. Moreover, the potential of the modulation well 5 will be increased or decreased mainly corresponding to the raising and lowering of the gate voltage of the modulation transistor TM.

In the present embodiment, the same drive is carried out to all the cells in the single accumulating period Sa shown in FIG. 8A. As also shown in FIG. 9, in the single accumulating period Sa shown in FIG. 8A, 0.0 V is applied to the ring gate (RG) 6, 2.5 V is applied to the transfer gate (TX) 13, 2.5 V is applied to the clear gate 14, 2.0 V is applied to the LOD gate 12, 1.0 V is applied to the drain D, and 1.0 V is applied to the source. The drain voltage is set to a relatively low value.

In the single accumulating period, the potential barrier of the transfer channel RT between the accumulation well 4 and the modulation well 5 is made sufficiently high by the transfer transistor TT. Moreover, the potential barrier of the unwanted electric charge discharging channel RL between the accumulation well 4 and the OD contact region 11 is made sufficiently high by the LOD transistor TL. Furthermore, the potential of the potential barrier of the transfer channel RT is made higher than the potential of the potential barrier of the unwanted electric charge discharging channel RL. The accumulation well 4 is set at a relatively high concentration, and its potential before the accumulation of the electric charges is relatively low. When the accumulation is started, the electric charges are generated by light entering from the opening region 2 of the photo-diode PD, and are accumulated in the accumulation well 4. FIG. 8A shows the potential increase by the accumulation of the electric charges, with a satin pattern.

In the present embodiment, the potential barrier of the unwanted electric charge discharging channel RL and the potential barrier of the transfer channel RT are sufficiently high (potential is high), and the electric charges generated by incident light are accumulated in the accumulation well 4, without being transferred to the modulation well 5. Even if extremely strong light enters, the potential barrier of the transfer channel RT is higher than the potential barrier of the unwanted electric charge discharging channel RL, therefore, the electric charges which overflow from the accumulation well 4 are discharged to the OD contact region 11 through the unwanted electric charge discharging channel RL, and will not flow into the modulation well 5.

In the transfer period shown in FIG. 8B, 0.0 V is applied to the ring gate (RG) 6, 0.0 V is applied to the transfer gate (TX) 13, 2.5 V is applied to the clear gate 14, 2.0 V is applied to the LOD gate 12, 4.0 V is applied to the drain D, and 0.0 V is applied to the source.

0 V is applied to the transfer gate 13, and the potential barrier of the transfer channel RT becomes sufficiently low. Accordingly, the electric charges accumulated in the accumulation well 4 in the above described single accumulating period Sa and in the parallel accumulating periods Sa, Sc, and Sn, as described later, flow into the modulation well 5 through the transfer channel RT. In addition, by setting the drain voltage to a relatively high voltage, the potential gradient is made large to facilitate the transfer of the electric charges.

In addition, the potential barrier of the discharging channel by the clear gate 14 is also set sufficiently high, and the electric charges stored in the modulation well 5 will not flow out into the discharging channel side. Moreover, also in the transfer period shown in FIG. 8B, all the cells become the reading cells and the same drive is carried out.

The reading period includes the signal modulation (S modulation) period for mainly reading the signal component (S), the noise modulation (N modulation) period for mainly reading the noise component (N), and the clear period to clear the residual electric charges in order to read the noise component. By reading the signal component and the noise component to compare, the picture signal, in which the cell variation and the various kinds of noises are removed, is obtained. Namely, in the reading period, the S modulation period, the clear period, and the N modulation period are carried out in this order.

The same control is carried out in the S modulation period and the N modulation period. In the S/N modulation period shown in FIG. 8C, with respect to the reading cell, as shown in the dashed line of FIG. 9, 2.5 V is applied to the ring gate (RG) 6, 2.5 V is applied to the transfer gate (TX) 13, 2.5 V is applied to the clear gate 14, 2.0 V is applied to the LOD gate 12, and 2.5 V is applied to the drain D. Vg−Vths (=2.5−Vths) arises at the source (Vg is the gate voltage and Vths is the threshold voltage of the channel at the time of the S modulation).

The reading is carried out for each line. Only each cell of one line (reading line) out of all the lines becomes the reading cell, and each cell of other lines (non-reading lines) is a non-reading cell. Then, upon completion of the reading of each reading cell from the reading line, the reading line shifts, and each cell of the following line becomes a reading cell, and the other cells become the non-reading cells. Similarly, the reading of the signal component (S modulation) or the reading of the noise component (N modulation) is carried out by shifting the reading line.

As for the reading cell, the potential barrier of the transfer channel RT is made high by the transfer transistor TT so that the electric charges stored in the modulation well 5 may not flow out into the accumulation well 4. Since the voltage of the ring gate 6 is made high, the source potential increases accordingly. The threshold voltage of the channel of the modulation transistor TM changes corresponding to the electric charges stored in the carrier pocket 10. Namely, the source potential of the modulation transistor TM becomes the one corresponding to the generated amount of the photo-generated electric charges, i.e., the incident light, because the photo-generated electric charges accumulated in the accumulation well 4 of the photo-diode PD are transferred to the carrier pocket 10.

In addition, as for the non-reading cell, as shown in the solid line of FIG. 9, 0.0 V is applied to the ring gate (RG) 6, 2.5 V is applied to the transfer gate (TX) 13, 2.5 V is applied to the clear gate 14, 2.0 V is applied to the LOD gate 12, and 2.5 V is applied to the drain D. Also in this case, Vg−Vths (=0−Vths) is generated in the source, however, since the voltage of the ring gate 6 is low, the output of the non-reading cell becomes a level sufficiently lower than the output of the reading cell. Therefore, only the output pixel signal of the reading cell appears at the source line.

In addition, the potential difference applied to the ring gate 6 of the reading cell and of the non-reading cell is made sufficiently high, therefore, even if, for example, the picture is dark or the like, the output pixel signal of the reading cell can be securely taken out from the source line.

In the clear period shown in FIG. 8D, as for the reading cell, as shown in the dashed line of FIG. 9, 1.5 V is applied to the ring gate (RG) 6, 2.5 V is applied to the transfer gate (TX) 13, 0.0 V is applied to the clear gate 14, 2.0 V is applied to the LOD gate 12, 2.5 V is applied to the drain D, and 5.0 V is applied to the source.

Accordingly, the potential barrier of the discharging channel by the clear gate 14 is lowered sufficiently, and the electric charges remaining in the modulation well 5 flow from the discharging channel to the discharging contact region 15. Accordingly, the photo-generated electric charges in the modulation well 5 are removed, thereby enabling the reading of the noise component (noise modulation).

On the other hand, as for the non-reading cell, as shown in the solid line of FIG. 9, 1.5 V is applied to the ring gate (RG) 6, 2.5 V is applied to the transfer gate (TX) 13, 2.5 V is applied to the clear gate 14, 2.0 V is applied to the LOD gate 12, 2.5 V is applied to the drain D, and 5.0 V is applied to the source. Accordingly, the potential barrier of the residual electric charge discharging channel by the clear gate 14 is kept high.

The reading of the non-reading cell out of the cells per each line after the blanking period passed in FIG. 7 has already been completed, however, as for the non-reading cells of the line before the blanking period passes; the reading has not been carried out yet. Then, in the non-reading cells, the electric charges are prevented from being discharged from the modulation well 5, by keeping the potential barrier of the discharging channel by the clear gate 14 high. The satin pattern portion with respect to the non-reading cell of FIGS. 8C and 8D indicates that the electric charges, which have not been read, are being stored in the modulation well 5.

According to the present embodiment, as described above, the parallel accumulation operation is carried out in the SIN modulation period and the clear period. FIGS. 8C and 8D show this parallel accumulation operation. Namely, in the reading period (SIN modulation and clear period), the photo-generated electric charges are accumulated in the accumulation well 4 by increasing the potential barrier of the transfer channel RT and the unwanted electric charge discharging channel RL. Accordingly, the reading period (modulation period and clear period) of the modulation transistor TM will be the accumulating period (parallel accumulating periods Ss, Sn, and Sc) for accumulating the photo-generated electric charges at the photo-diode PD side. In addition, in the parallel accumulating period Ss and Sn of FIG. 8C, and the parallel accumulating period Sc of FIG. 8D, the drain voltage is higher as compared with that of the single accumulating period Sa, and thus the conditions of accumulating the photo-generated electric charges differ. Moreover, as shown in FIGS. 8C and 8D, the conditions for accumulating the photo-generated electric charges differ slightly between the reading cell and the non-reading cell.

Thus, in the single accumulating period Sa, the S/N modulation period, and the clear period, accumulation of the photo-generated electric charges are carried out in all the cells, and the accumulation time for each cell will be approximately one frame period as shown in FIG. 7. A provision is made to separately constitute the accumulation well 4 for accumulating the electric charges which is formed at the photo-diode PD side, and the modulation well 5 which is formed at the modulation transistor TM side, and control the potential barrier of the transfer channel RT between the both by the transfer transistor TT. Accordingly, the accumulation well 4 and the modulation well 5 can be set in the reading period and the parallel accumulating period of the same period, and thus the frame rate can be increased.

The PD clear period shown in FIG. 8E is adopted in a high-speed shutter mode or in a low-speed shutter mode as will be described later. As shown in FIG. 9, 0.0 V is applied to the ring gate (RG) 6, 2.5 V is applied to the transfer gate (TX) 13, 2.5 V is applied to the clear gate 14, 0.0 V is applied to the LOD gate 12, 4.0 V is applied to the drain D, and the source impedance is made high. In addition, the driving voltage in case that the PD clear period is used in the normal mode is also the same as that of FIG. 8E.

The potential barrier of the unwanted electric charge discharging channel RL is made sufficiently low by lowering the LOD gate, and the unwanted electric charges accumulated in the accumulation well 4 are discharged from the unwanted electric charge discharging channel RL to an external signal line through the OD contact region 11. In addition, in case that the PD clear operation is adopted in the normal mode as shown in FIG. 7, the residual electric charges will not be left in the modulation well 5 portion of FIG. 8E.

Driving Sequence

Next, the operation sequence with respect to each of the normal mode, the high-speed shutter mode, and the low-speed shutter mode will be explained. FIG. 10 is a timing chart showing the driving sequence in the normal mode.

Approximately the same driving as that of the above described normal mode of FIG. 7 is carried out in the normal mode of FIG. 10. In addition, in the normal mode of FIG. 10, the PD clear period in the single PD clear period and in the line-out period is omitted. Moreover, in FIG. 10, the single accumulating period Sa (line-out period), and the blanking period of FIG. 7 are combined to be shown as one pulse shape. In addition, as described above, the single accumulating period Sa is the time required for transferring data from the line memory, and actually needs more time than the blanking period.

In the normal mode of FIG. 10, the period of one frame period excluding the transfer period is the accumulating period for each cell. The leading timing of the following frame after the completion of the accumulating period is set to the transfer period. In the transfer period, the photo-generated electric charges being stored in the accumulation well 4 are transferred to the carrier pocket 10 in the modulation well 5, and are accumulated. Upon completion of the transfer period, the single accumulating period and the blanking period are repeated, and the reading from the cell of each line is carried out continuously. As described above, the transfer period includes two transfer periods, i.e., the transfer period 1, and the transfer period 2. As shown in FIG. 3, in the transfer period 1, the pixel signal of all the sensor cells in the region B is transferred to the modulation well 5 from the accumulation well 4. In the transfer period 2, the pixel signal of all the sensor cells in the regions A and C is transferred to the modulation well 5 from the accumulation well 4.

Since the parallel accumulating period is set up using a timing common to the blanking period, it is not necessary to prepare another period for the accumulation, and thus the frame rate can be increased.

FIG. 11 is a timing chart which shows the driving sequence by the same method as that of FIG. 10.

FIG. 11A shows the driving sequence in the high-speed shutter mode. The high-speed shutter mode is used, for example, for shortening the accumulating period.

In addition, in the conventional examples, since a provision is made to discharge the residual electric charges of the first well upon completion of the blanking period, the high-speed shutter mode or the like according to the present embodiment cannot be implemented.

For example, when extremely bright light is incident upon the photo diode PD, the amount of the electric charges which flow into the modulation well 5 of each cell increases extremely, and the picture based on the pixel signal read from each cell will be whitish (bright or washed out) as a whole and the contrast thereof will degrade. In such a case, the high-speed shutter mode is adopted. In the high-speed shutter mode, as shown in FIG. 11A, the PD clear period is set to the line-out period of an arbitrary position in one frame period. In addition, in FIG. 11, the blanking period and the line-out period are shown as one pulse as described above. In FIG. 11, an example of setting the PD clear period at the last timing of the line-out period is shown; however, the PD clear period may be set at any timing as long as it is within the line-out period of each pulse. Moreover, the accumulating period is the period from the end of the PD clear of the preceding frame until the start of the transfer period.

As shown in FIG. 8E, in the PD clear period, the electric charges accumulated in the accumulation well 4 are discharged to the outside through the OD contact region 11. Accordingly, the photo-generated electric charges generated after the completion of the PD clear period are accumulated in the accumulation well 4. After the completion of the PD clear period, the single accumulating period Sa and the parallel accumulating periods Ss, Sc, and Sn are cyclically repeated until the completion of the frame period. Thus, after the accumulation is carried out only for the time shorter than the one frame period corresponding to the position of the PD clear period, the photo-generated electric charges accumulated in the accumulation well 4 are transferred to the modulation well 5 in the leading transfer period of the frame.

The reading is the same as that of the normal mode, and while the reading line is sequentially shifting, the reading of all lines completes in one frame period. In addition, as for the cell where the reading has not been completed, as shown in FIG. 8E, the electric charges are being stored in the modulation well 5, and can be read in one frame period regardless of the accumulating period based on the position of the PD clear period.

For example, in case that the PD clear period is set to the approximate center of one frame period, the accumulating period will be approximately a half of one frame period, and the amount of the electric charges which flow into the modulation well 5 will be approximately a half of that of the normal mode, and the brightness of the picture based on the pixel signal read from each cell can be made adequate. Thereby, a picture having sufficient contrast, though it is bright, can be obtained.

In addition, since the PD clear period can be easily set up by applying the driving voltage shown in FIG. 9 to each portion, the PD clear period can be arranged in an arbitrary position corresponding to the brightness of the picture. Therefore, the accumulating period can be set up without restraint, and the pixel signal having an optimal level corresponding to the brightness of the picture can be obtained from each cell.

Relationship Between Continuous Imaging and PD Clear

Incidentally, it is conceivable that the PD clear period is set to an arbitrary timing independently form the blanking period in the frame period at the time of continuous imaging. However, if doing so, the PD clear operation will occur in the middle of the reading operation. In this case, in the subsequent circuits of the line-out circuit (equivalent to the signal output circuit 69 of FIG. 5), a delay will occur in the picture signal. In order to correct the offset of the output timing of this picture signal, a process of stopping operations of the line-out circuit, the signal-processing circuit which is not shown, or the like, will be needed, and thus the circuit thereof will be complicated.

In the present embodiment, a provision is made to generate the PD clear period in synchronization with the blanking period. Namely, as shown in FIG. 9, the PD clear period is inserted immediately after the end of each blanking period. Namely, the period, which can be set up as the PD clear period, can be provided a number of times based on the number of the lines (number of blanking) in one-frame period.

As shown in FIG. 9, among the PD clear periods, which can be set up, in the PD clear period at the timing when the PD clear should be actually carried out, the driving voltage shown in FIG. 8E is set up, and in other clear periods, which can be set up, i.e., in the PD clear period when the PD clear is actually not carried out, the same driving voltage as that of the single accumulation shown in FIG. 8A is set up.

That is, in the present embodiment, the PD clear period can be set up in a period immediately after the blanking period, in other words, at the start timing of the single accumulating period (line-out period). The PD clear period for actually carrying out the PD clear operation is generated in the period corresponding to the accumulating period, which is going to be set up, among each line-out period in the frame.

Assuming that the entire period from the blanking period to the following blanking period is called the single accumulating period (line-out period), the PD clear period will be set up in this single accumulating period (line-out period), and in the example of FIG. 9, there is shown an example of setting up the PD clear period at the leading timing of the single accumulating period (line-out period). In addition, the PD clear period may be set to an arbitrary timing in the single accumulating period (line-out period). For example, the PD clear period can be suitably set to an arbitrary timing in the single accumulating period (line-out period) corresponding to the setup of the shutter speed.

In addition, in the period, which can be set up as the PD clear period and in which the PD clear operation is actually not carried out, as described above, the same setup as that of the single accumulating period is carried out. Accordingly, the length of the single accumulating period differs slightly between the single accumulating period in which the PD clear period for actually carrying out the PD clear operation exists, and the other single accumulating periods. However, the PD clear period is an extremely short time period, and the influence with or without the PD clear period is extremely small. In addition, as described above, the time from the end timing of the PD clear period to the start of the leading transfer period in the following frame is the accumulating period.

Moreover, in the normal mode, as shown in FIG. 7, the PD clear period may be generated at the timing immediately before the start of the blanking period.

Since the PD clear period occurs in synchronization with the blanking period, a continuous picture signal can be obtained with or without the PD clear period, also in a continuous imaging mode. Accordingly, even if the PD clear operation occurs, it is not necessary to stop the operation of the line-out circuit, the signal-processing circuit, or the like, and thus the circuit configuration can be simplified.

FIG. 11B shows the driving sequence in the low-speed shutter mode.

The low-speed shutter mode is used, for example, for making the accumulating period longer than one frame period. For example, in case that light incident upon the photo-diode PD is dark, the amount of the electric charges which flow into the modulation well 5 of each cell will decrease, and the picture based on the pixel signal read from each cell will be dark as a whole. In such a case, the low-speed shutter mode is adopted. In the low-speed shutter mode, while the PD clear period is inserted once per a plurality of frame periods, the transfer period is inserted once per a plurality of frames.

Also in this case, the PD clear period is set up at an arbitrary timing of the line-out period which is synchronized with the blanking period.

In the example of FIG. 11B, the PD clear period is inserted once per two frame periods, and the transfer period is set at the leading timing of the frame of one and a half frame periods after the completion of this PD clear period. Therefore, the accumulating period in this case will be one and a half frame periods. Thereby, a picture having approximately one and a half times brightness as compared with the normal mode can be obtained. In addition, in the case of FIG. 10B, the reading from each cell will be carried out only once per two frame periods, and the frame rate will be a half of the normal mode.

By adopting the shutter mode of FIGS. 11A and 11B, the accumulating period can be set up without restraint and an optimal picture corresponding to the brightness of incident light can be obtained.

In addition, also in the low-speed shutter mode, the reading is carried out within approximately one frame period after the transfer period. Conventionally, the accumulated photo-generated electric charges are also discharged by reading, therefore, in the following one frame period after reading, a dummy-reading involving the clear operation which does not contribute to the picture signal, cannot be carried out. On the other hand, in the present embodiment, since the reading operation can be carried out simultaneously with the accumulation of the photo-generated electric charges, the dummy-reading involving the clear operation can be carried out even in the following one frame period after a reading. Accordingly, there is an advantage that the configuration of the logic circuit or the like that carries out the reading can be simplified.

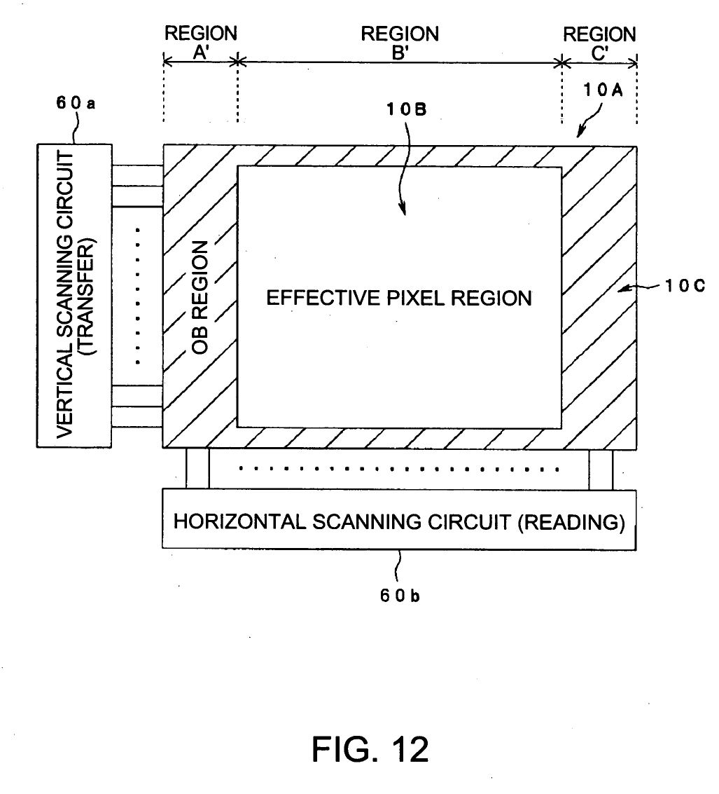

In the above example, as shown in FIG. 3, in the imaging face 10A, the region including the effective pixel region 10B and the region including only the non-effective pixel region 10C are divided in the vertical direction. However, the following modifications may be implemented. That is, as shown in FIG. 12, the region may be divided into a region B′ that includes the effective pixel region 10B, and regions A′ and C′ that include only the sensor cell 3 of the non-effective pixel region 10C. In FIG. 12, the imaging face 10A is divided, in the horizontal direction of the two dimensional matrix, in the region that includes the effective pixel region 10B, and the region that includes only the non-effective pixel region 10C.

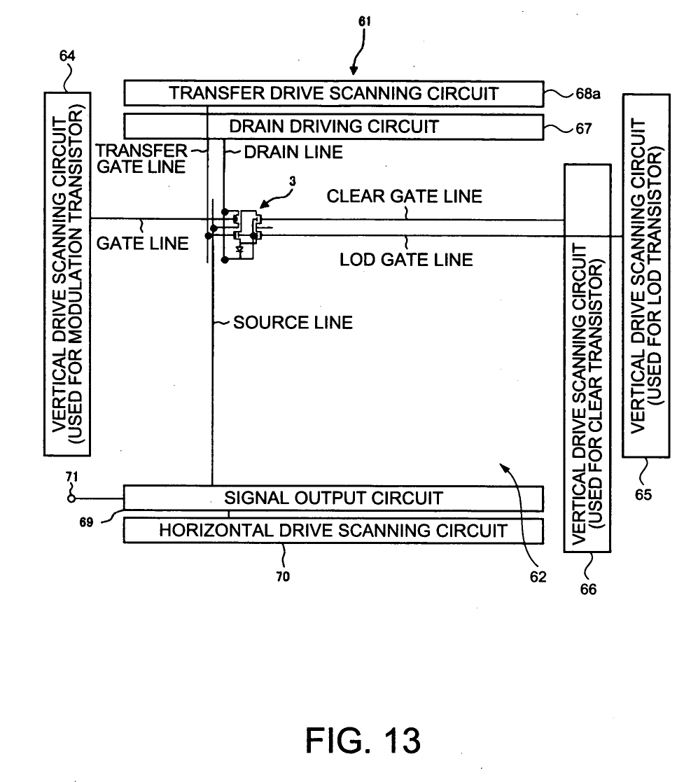

In this case, the circuit configuration of the entire solid state imaging device will be the one shown in FIG. 13. FIG. 13 is a view of the circuit configuration of the entire solid state imaging device in this case. In FIG. 13, the same configuration elements as those of FIG. 5 are given the same numerals, and the description thereof is omitted. Here, the transfer drive scanning circuit 68 in FIG. 5 is provided as a transfer drive scanning circuit 68a which has the transfer gate line in the vertical direction. Therefore, in the transfer period 1, by simultaneously providing a gate signal to the transfer gate 13 of each transfer transistor TT in the region B′ from the transfer drive scanning circuit 68, the pixel signal of all the sensor cells in the region B′ are batch-transferred to the modulation well 5 from the accumulation well 4.

In the transfer period 2, by simultaneously providing the gate signal to the transfer gate 13 of each transfer transistor TT in the regions A′ and C′ from the transfer drive scanning circuit 68, the pixel signal of all the sensor cells in the regions A′ and C′ are batch-transferred to the modulation well 5 from the accumulation well 4. Accordingly, the pixel signal of a plurality of sensor cells in the imaging face 10A is not batch-transferred for all the pixels, but is transferred separately at two times.

Moreover, as the region determining the black level in this modification, the pixel signal of the sensor cells of the non-effective pixel region 10C in the horizontal direction of the effective pixel region 10B, i.e., of the non-effective pixel regions on the right and left in FIG. 12, is used. According to this, because the pixel signal of the sensor cell of the non-effective pixel regions having different exposure time is not used, the difference in the dark output between the effective pixel region 10B and the non-effective pixel region 10B which determines the black level will be diminished to some extent. As a result, a good quality picture can be obtained.

In addition, in the above two configuration examples, with being divided into two; the region including the effective pixel region, and the region including only the non-effective pixel region, the transfer period is divided into two corresponding to these two regions, and there is one region that includes the effective pixel region and two regions that include only the non-effective pixel region. Specifically, there are three regions, the region A, the region B, and the region C in FIG. 3, and there are three regions; the region A′, the region B′ and the region C′in FIG. 12. Then, a provision may be made to transfer these three regions separately in order. For example, in FIG. 3, as for the order, an order of the region A, the region B, and the region C may also work, and an order of the region B, the region C, and the region A, or the like may work as well. In FIG. 12, as for the order, an order of the region A′, the region B′, and the region C′ may also work, and an order of the region B′, the region C′, and the region A′, or the like may work as well.

According to the above described configuration, in the formula (1), the number of pixels N is not the number of whole pixels, but is divided into the number of pixels in a region that includes the effective pixel region, and the number of pixels in other regions, therefore, as a result, the maximum amount of current supply which is required instantaneously at the time of the transfer decreases. That is, a provision is made to transfer the pixel signal of the sensor cell that includes the effective pixel region and the pixel signal of the sensor cell in the non-effective pixel region at separate timings, therefore, the amount of current which is required instantaneously at the time of the transfer decreases. Consequently, the driving circuit can be made smaller, and thus chips for the solid state imaging device can be made smaller.

As described above, according to the present embodiment, the solid state imaging device which reduces the maximum amount of current supply required for turning on the transfer transistor, and a method of driving the same can be realized.

The present invention is not limited to the above described embodiments, and various modifications, variations, or the like can be made without changing the scope of the present invention.

1. A solid state imaging device including a plurality of pixels arranged in a matrix form that generate photo-generated electric charges corresponding to incidence light, the device comprising:
an effective pixel region used for imaging; and
a non-effective pixel region provided separately from the effective pixel region,
wherein each pixel includes:
an accumulation well that accumulates the photo-generated electric charges;
a modulation transistor; and
a transfer control element that transfers the photo-generated electric charges accumulated in the accumulation well to the modulation transistor; and
wherein when transferring the photo-generated electric charges accumulated in the accumulation well to the modulation transistor by the transfer control element, transfer of the photo-generated electric charges in the effective pixel region and the photo-generated electric charges that do not include the photo-generated electric charges in the effective pixel region is carried out separately at least two times.

2. The solid state imaging device according to claim 1, wherein:
the transfer is carried out to at least two regions that are divided in one axis direction of the matrix region that is two dimensional; and
a first region of the two regions includes the effective pixel region, and a second region of the two regions does not include the effective pixel region.

3. The solid state imaging device according to claim 2, wherein the photo-generated electric charges in the first region are batch transferred.

4. The solid state imaging device according to claim 2, wherein the photo-generated electric charges in the second region are batch transferred.

5. The solid state imaging device according to claim 2, wherein the second region comprises an optical black region.

6. The solid state imaging device according to claim 2, wherein the first region includes an optical black region and a black level is determined based on the signal of the photo-generated electric charges in the optical black region.

7. A method of driving a solid state imaging device including a plurality of pixels arranged in a matrix form that generate photo-generated electric charges corresponding to incidence light, the method comprising:
providing an effective pixel region for imaging; and
providing a non-effective pixel region separately from the effective pixel region;
providing each pixel with:
an accumulation well that accumulates the photo-generated electric charges;
a modulation transistor; and
a transfer control element that transfers the photo-generated electric charges accumulated in the accumulation well to the modulation transistor; and
when transferring the photo-generated electric charges accumulated in the accumulation well to the modulation transistor by the transfer control element, transferring the photo-generated electric charges in the effective pixel region and transferring the photo-generated electric charges that do not include the photo-generated electric charges in the effective pixel region.

8. The method according to claim 7 wherein the photo-generated electric charges in the effective pixel region and the photo-generated electric charges that do not include the photo-generated electric charges in the effective pixel region are transferred separately at least two times.

9. The method according to claim 7, wherein:
the transfer is carried out to at least two regions that are divided in one axis direction of the matrix region that is two dimensional; and
a first region of the two regions includes the effective pixel region, and a second region of the two regions does not include the effective pixel region.

10. The method according to claim 9, wherein the photo-generated electric charges in the first region are batch transferred.

11. The method according to claim 9, wherein the photo-generated electric charges in the second region are batch transferred.

12. The method according to claim 9, wherein the second region comprises an optical black region.

13. The method according to claim 9, wherein the first region includes an optical black region and a black level is determined based on the signal of the photo-generated electric charges in the optical black region.
